(19) United States
(12) Patent Application Publication
(10) Pub. No.: US 2015/0184292 A1
(43) Pub. Date: Jul. 2, 2015

(54) SYSTEMS AND METHODS FOR PREVENTING MIXING OF TWO GAS STREAMS IN A PROCESSING CHAMBER

(71) Applicant: Lam Research Corporation, Fremont, CA (US)

(72) Inventors: Arun Keshavamurthy, Bangalore (IN); Ravi Turamari, Bangalore (IN); Vasant Malali, Bangalore (IN)

(21) Appl. No.: 14/570,270

(22) Filed: Dec. 15, 2014

Related U.S. Application Data
(60) Provisional application No. 61/921,672, filed on Dec. 30, 2013.

(51) Int. Cl. C23C 16/455; C23C 16/52; C23C 16/48

(52) U.S. Cl. CPC C23C 16/455; C23C 16/482; C23C 16/52

(57) ABSTRACT

A substrate processing system includes a processing chamber. A first gas inlet supplies a first gas to the processing chamber and is arranged in a first horizontal plane. A second gas inlet supplies a second gas that is different than the first gas to the processing chamber. The second gas inlet is arranged in a second horizontal plane that is spaced from the first horizontal plane. A first gas outlet removes the first gas from the processing chamber and is arranged in a third horizontal plane that is horizontally spaced from and between the first and second horizontal planes. A second gas outlet removes the second gas from the processing chamber and is arranged in a fourth horizontal plane that is horizontally spaced from and between the second and third horizontal planes.

### CROSS-REFERENCE TO RELATED APPLICATIONS

This application claims the benefit of U.S. Provisional Application No. 61/921,672, filed on Dec. 30, 2013. The entire disclosure of the application referenced above is incorporated herein by reference.

### FIELD

The present disclosure relates to substrate processing systems, and more particularly to systems and methods for preventing mixing of two gas streams in a processing chamber.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to deposit dielectric film on a substrate. Sometimes the film deposition is performed using chemical vapor deposition (CVD), plasma-enhanced CVD (PECVD), atomic layer deposition (ALD) or plasma-enhanced ALD (PEALD). While PECVD processes are used to deposit thin film, PECVD is generally not controlled sufficiently to deposit ultra-thin film because of its relatively high deposition rates. While ALD can be used to deposit ultra-thin film, ALD may be too slow because ALD constructs the ultra-thin film one atomic layer at a time.

Investigation is currently being directed towards other CVD processes with deposition rates that are lower than PECVD but higher than ALD. One CVD process uses ultra-violet (UV) radiation as an energy source for a CVD reaction. The UV light is incident on reactants that flow over a surface of a substrate such as a semiconductor wafer. The UV light is transmitted to the substrate surface through a window that forms part of the processing chamber. The window needs to be purged actively with an inert gas to prevent deposition of the film. As film is deposited on the quartz window, UV transmission degrades. Therefore, the process needs to be stopped regularly to clean the window.

### SUMMARY

A substrate processing system includes a processing chamber. A first gas inlet supplies a first gas to the processing chamber and is arranged in a first horizontal plane. A second gas inlet supplies a second gas that is different than the first gas to the processing chamber and is arranged in a second horizontal plane that is spaced from the first horizontal plane. A first gas outlet removes the first gas from the processing chamber and is arranged in a third horizontal plane that is horizontally spaced from and between the first horizontal plane and the second horizontal plane. A second gas outlet removes the second gas from the processing chamber and is arranged in a fourth horizontal plane that is horizontally spaced from and between the second horizontal plane and the third horizontal plane.

In other features, the first gas comprises purge gas and the second gas comprises process gas. The first gas is directed across a component in the processing chamber and the second gas is directed across a substrate arranged on a pedestal in the processing chamber. In other features, the component includes an ultraviolet window.

In other features, a surface of the processing chamber comprises an ultraviolet (UV) window. A UV light source is configured to direct UV light through the UV window onto a substrate arranged on a pedestal while the first gas and the second gas are flowing. The first gas comprises purge gas and the second gas comprises process gas. The first gas inlet directs the purge gas across a surface of the UV window while the second gas inlet directs the process gas across a surface of the substrate.

In other features, the first gas inlet and the second gas inlet comprise first and second manifolds, respectively, each including a plurality of holes located in the first and second horizontal planes, respectively. The first gas outlet and the second gas outlet comprise third and fourth manifolds, respectively, each including a plurality of holes located in the third and fourth planes, respectively.

In other features, a controller is configured to flow the second gas across a substrate arranged on a pedestal in the processing chamber after the first gas is flowing and to not flow the second gas when the first gas is not flowing.

In other features, the first horizontal plane and the second horizontal plane are horizontally spaced by a first distance. The first horizontal plane and the third horizontal plane are spaced between 2.5% and 25% of the first distance. The second horizontal plane and the fourth horizontal plane are spaced between 2.5% and 25% of the first distance.

A method for processing a substrate includes supplying a first gas to a processing chamber using a first gas inlet that is arranged in a first horizontal plane; supplying a second gas that is different than the first gas to the processing chamber using a second gas inlet that is arranged in a second horizontal plane that is horizontally spaced from the first horizontal plane; removing the first gas from the processing chamber using a first gas outlet that is arranged in a third horizontal plane that is horizontally spaced from and between the first horizontal plane and the second horizontal plane; and removing the second gas from the processing chamber using a second gas outlet that is arranged in a fourth horizontal plane that is horizontally spaced from and between the second horizontal plane and the third horizontal plane.

In other features, the first gas comprises purge gas and the second gas comprises process gas. The method further includes directing the first gas across a component in the processing chamber and directing the second gas across a substrate arranged on the pedestal. In other features, the component includes an ultraviolet window.

In other features, a surface of the processing chamber comprises an ultraviolet (UV) window. The method includes directing UV light from a UV light source through the UV window onto a substrate arranged on a pedestal in the processing chamber while the first gas and the second gas are flowing. The first gas comprises purge gas and the second gas comprises process gas. The first gas inlet directs the purge gas across a surface of the UV window while the second gas inlet directs the process gas across a surface of the substrate.

In other features, the first gas inlet and the second gas inlet comprise first and second manifolds, respectively, each including a plurality of holes arranged in the first and second horizontal planes, respectively. The first gas outlet and the second gas outlet comprise third and fourth manifolds, respectively, each including a plurality of holes arranged in the third and fourth horizontal planes, respectively.

In other features, the method includes flowing the second gas across a substrate arranged on a pedestal in the processing chamber after the first gas is flowing and not flowing the second gas when the first gas is not flowing.

In other features, the first horizontal plane and the second horizontal plane are horizontally spaced by a first distance. The first horizontal plane and the third horizontal plane are spaced between 2.5% and 25% of the first distance. The second horizontal plane and the fourth horizontal plane are spaced between 2.5% and 25% of the first distance.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a processing chamber according to the present disclosure;

FIGS. 2A and 2B are perspective views of processing chambers illustrating first and second gas inlets and outlets that are arranged according to the prior art;

FIGS. 3A and 3B are perspective views of the processing chamber of FIGS. 2A and 2B illustrating flow of the first and second gases between the corresponding inlets and outlets according to the prior art;

FIG. 4 illustrates a model of the first and second gas flows of FIGS. 2A and 2B according to the prior art;

FIG. 5 is a perspective view of the processing chamber illustrating first and second gas inlets and outlets that are arranged according to the present disclosure;

FIG. 6 is a perspective view of the processing chamber of FIG. 5 illustrating flow of the first and second gases from the inlets to the outlets according to the present disclosure;

FIG. 7 illustrates a model of the first and second gas flows according to the present disclosure; and

FIG. 8 illustrates a method for operating a process chamber with first and second gases without mixing.

In the drawings, reference numbers may be reused to identify similar and/or identical elements.

### DETAILED DESCRIPTION

The present disclosure relates to systems and methods for flowing a first gas stream and a second gas stream within the same processing chamber while minimizing inter-mixing and resultant dilution. In some examples, the processing chamber includes a vacuum chamber. For example only, a first gas stream provides purge gas flow to prevent a second gas stream from reaching one or more sensitive components. The second gas stream may be used to provide reactants near a substrate surface to promote growth of a film on the substrate surface. The present disclosure describes systems and methods for flowing first and second gas streams in the same processing chamber without convectively mixing and diluting each other.

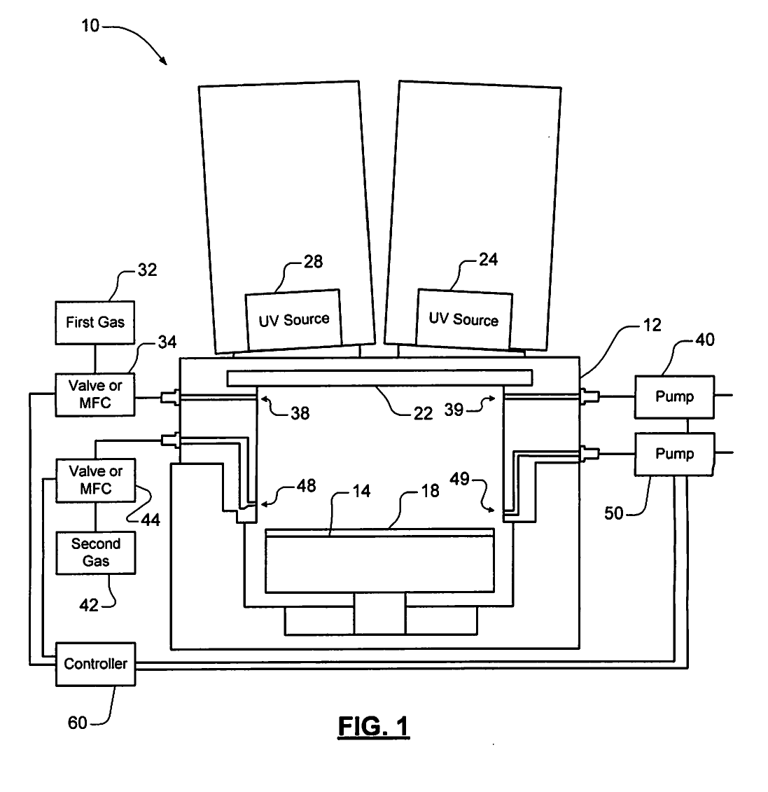

Referring now to FIG. 1, a substrate processing system 10 includes a processing chamber 12 including an upper surface, a lower surface and side walls. A pedestal or other mechanism identified at 14 may be provided to support a substrate 18. The substrate 18 may include a semiconductor wafer. A first gas stream may be supplied across a surface or component 22. A second gas stream may be supplied across a surface or component such as the substrate 18. The first gas stream may be used to protect the component 22 when the second gas stream is flowing. For example only, the component 22 may include an ultraviolet (UV) window. The substrate processing system may further include UV sources 24 and 28 that can be used to direct UV light onto the substrate 18 through the UV window. The UV window may be made of quartz or other suitable material.

The first gas stream may be supplied by a first gas supply 32 via a flow control device 34 such as a valve or mass flow controller (MFC) to a first gas inlet 38. A pump or other device 40 may be used to evacuate the first gas stream from the processing chamber 12 via a first gas outlet 39. The second gas stream may be supplied by a second gas supply 42 via a flow control device 44 such as a valve or mass flow controller (MFC) to a second gas inlet 48. A pump or other device 50 may be used to evacuate the second gas stream from the processing chamber 12 via a second gas outlet 49. In some examples, the first gas stream is purge gas, the second gas stream is process gas and the component 22 includes an ultraviolet (UV) window. A controller 60 may be used to control the flow control devices 34 and 44 and the pumps 40 and 50.

The arrangement in FIG. 1 can be used for ultra-thin film deposition using UV as a reaction source. The first gas stream enters the processing chamber 12 through the inlet 48 close to the surface of the substrate 18 at the bottom of the processing chamber 12 and exits the chamber through the outlet 49 that is diametrically opposite to the inlet 48.

UV light is transmitted to the surface of the substrate 18 through the UV window at the top of the chamber from the UV sources 24 and 28. The second gas stream reacts on the surface of the substrate 18 under the influence of UV light and an ultra-thin film layer is formed. It is also possible for the reactants to diffuse near the UV window and to deposit the same film on the UV window. The deposition of the film on the UV window degrades the transmission of UV energy through it, thereby affecting the deposition rate and uniformity on the substrate.

Therefore, the first gas stream is maintained near the UV window to avoid film deposition on the UV window. The first gas enters and leaves the process chamber 12 through the first gas inlet 38 and the first gas outlet 39 adjacent to the UV window. If the first and second gases mix convectively, the gases are diluted which leads to non-uniform film deposition on the substrate 18 and the UV window. Therefore, it is desirable to avoid convective mixing and to have the first and second gases leave the chamber through their respective outlets without the gas streams coalescing inside the process chamber 12.

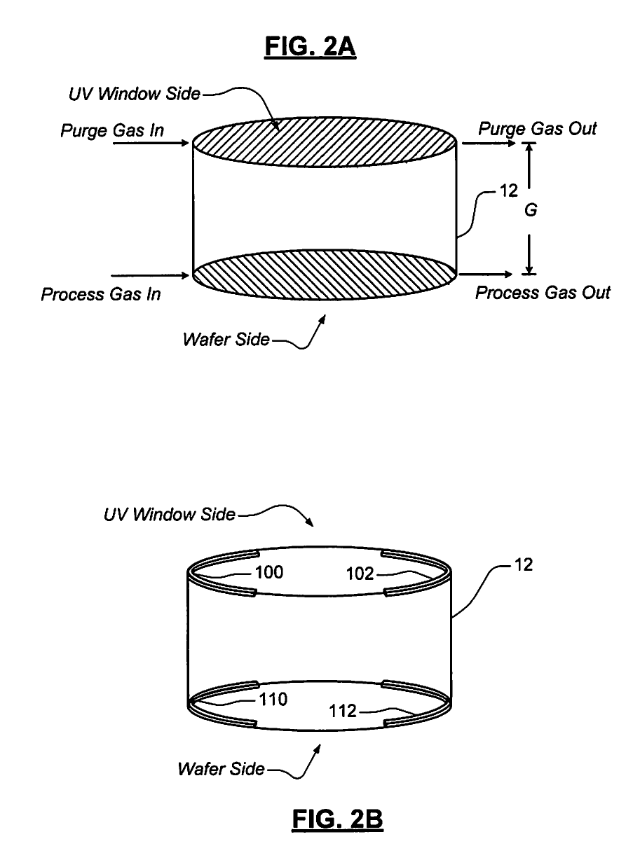

Referring now to FIGS. 2A and 2B, first and second gas inlets and outlets are shown. In FIG. 2A, the first gas inlet and outlet are arranged adjacent to the component to be protected (in this example, a process chamber side of the UV window). The second gas inlet and outlet are arranged adjacent to the substrate 18. In FIG. 2B, the first gas inlet and outlet may include manifolds 100 and 102, respectively. Likewise, the second gas inlet and outlet may include manifolds 110 and 112, respectively. In some examples, the manifolds are arcuate-shaped.

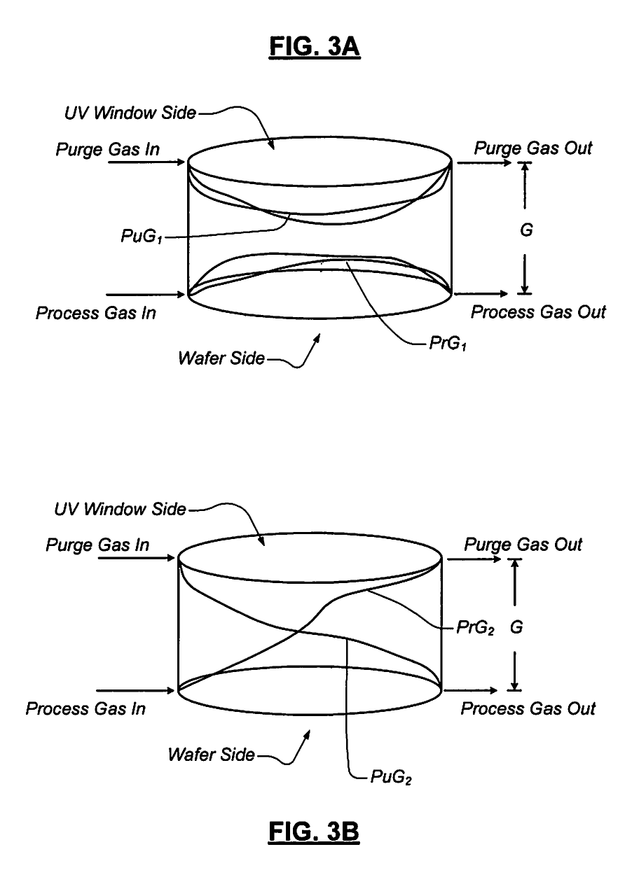

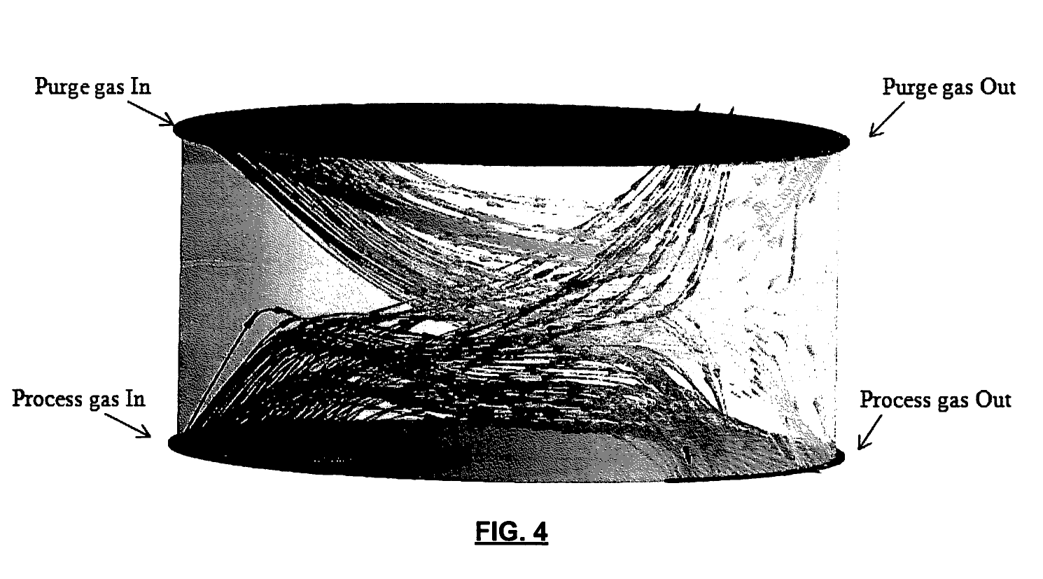

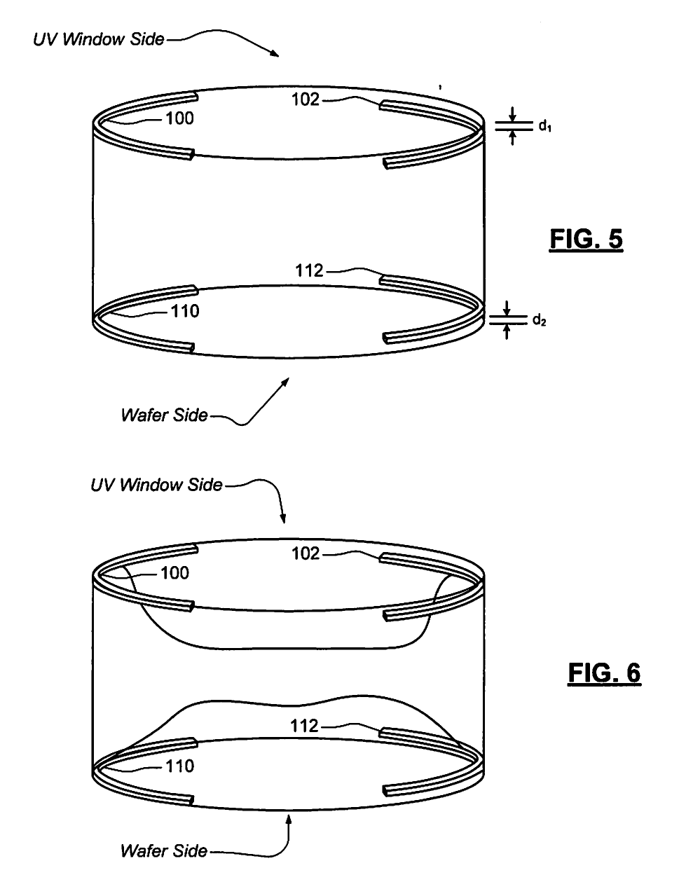

Referring now to FIGS. 3A and 3B, flow of the first and second gases from the inlets to the outlets is shown. When the first gas inlet is arranged in a same plane as the first gas outlet and the second gas inlet is arranged in a same plane as the second gas outlet, some of the first and second gases flows directly to the corresponding first and second outlets in the desired manner (as shown in FIG. 3A) but some of the flow intermixes as shown in FIG. 3B. The flow patterns show that both the first and second gases leave the chamber through both of the outlets. This indicates convective mixing of the two streams, which is not desirable. In FIG. 4, a flow model illustrates the undesirable mixing of the first and second gas flows with this arrangement.

Referring now to FIG. 5, the processing chamber includes first and second gas inlets and outlets that are arranged to prevent mixing of the first and second gas streams. The first gas outlet is located in a horizontal plane that is spaced further away from the component to be protected than a horizontal plane including the first gas inlet. The second gas outlet is located in a horizontal plane that is spaced further away from the substrate than a horizontal plane including the second gas inlet. In other words, the first gas inlet and the second gas inlet are spaced farther apart than the first gas outlet and the second gas outlet. In some examples, the horizontal planes are parallel to a plane including the substrate and to a plane including a lower surface of the UV window.

More particularly, in some examples the first gas inlet or manifold is arranged in a first horizontal plane adjacent to the component to be protected. The first gas outlet or manifold is arranged in a second horizontal plane that is spaced a predetermined distance away from the first horizontal plane in a direction away from the component to be protected by the first gas. The second gas inlet or manifold is arranged in a third horizontal plane adjacent to the substrate. The second gas outlet or manifold is arranged in a fourth horizontal plane that is spaced a predetermined distance away from the third horizontal plane in a direction away from the substrate.

For example only, the first gas inlet or manifold is arranged in the first horizontal plane and the second gas inlet or manifold is arranged in the third horizontal plane. The first horizontal plane and the third horizontal plane may be spaced a first predetermined distance apart. In some examples, the first and third horizontal planes may be 5-10″ apart.

In some examples, the first and second gas inlet manifolds are 60 mils wide in the horizontal direction. The first gas outlet manifold is approximately 110 mils wide and the second gas outlet manifold is approximately 220 mils wide in the horizontal direction. The distance between the first and second horizontal planes and the third and fourth horizontal planes is greater than 2.5% and less than 25% of the distance between the first and third horizontal planes. For example only, the distance between the first and second horizontal planes may be 0.25″ to 0.75″. For example only, the distance between the third and fourth horizontal planes may be 0.25″ to 0.75″.

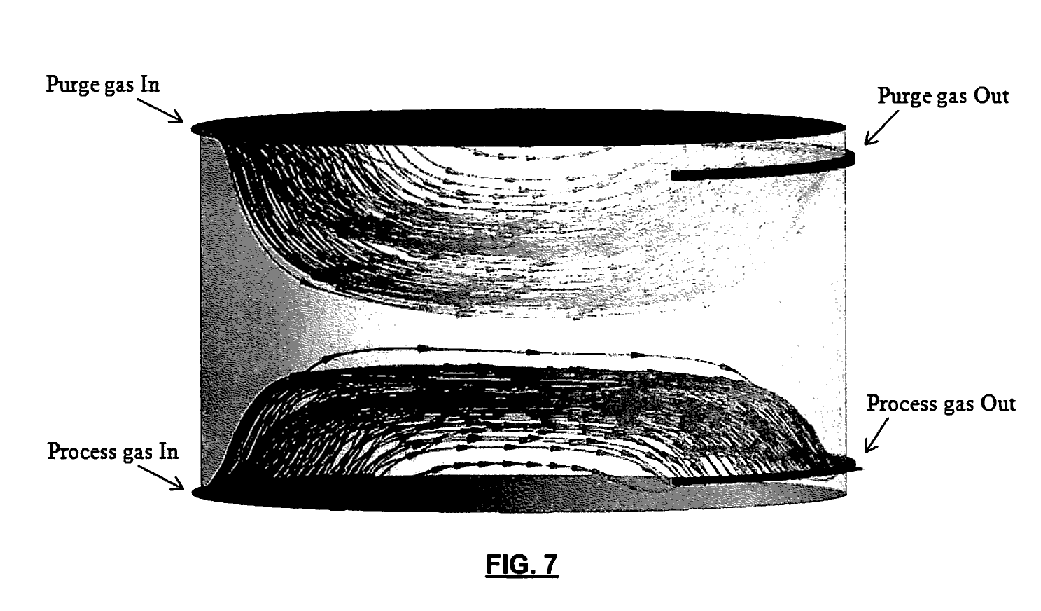

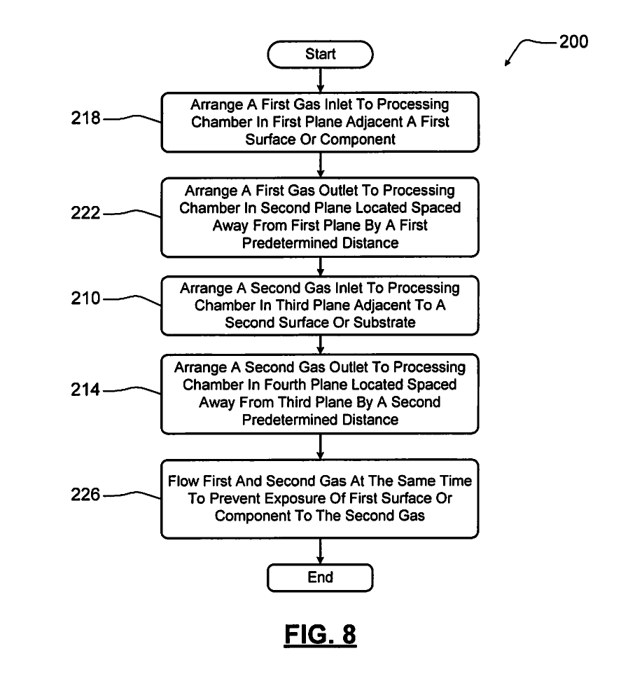

Referring now to FIGS. 6 and 7, by providing spacing of the first and second gas inlets and outlets as described herein, flow of the first and second gas streams from the inlets to the outlets occurs without mixing. In FIG. 6, the first and second gas flows do not convectively mix. The gas flow pattern shows that the first and second gas flows leave the processing chamber through their respective outlets and do not mix convectively within the processing chamber. The fact that the corresponding inlet and outlet planes for both gases are on different horizontal planes helps keep the two streams separate in the processing chamber without convective mixing. In FIG. 7, modeling of the first gas and second gas flows is shown.

Referring now to FIG. 8, a method 200 for operating a process chamber with two gas streams without mixing is shown. At 210, a first gas inlet is arranged in a first horizontal plane adjacent to a component to be protected. At 212, a first gas outlet is arranged in a second horizontal plane that is spaced away from the first horizontal plane in a direction away from the component. At 220, a second gas inlet is arranged in a third horizontal plane adjacent to the substrate. At 224, a second gas outlet is arranged in a fourth horizontal plane that is located spaced from the third horizontal plane by a predetermined distance. At 226, the flow of the first and second gases occurs at the same time to process the substrate while preventing intermixing.

Each of the inlet manifolds described herein may be fed by multiple gas supply tubes to provide uniform gas delivery. Likewise, each of the outlet manifolds described herein may be connected to multiple gas retrieval tubes to provide uniform gas recovery.

The present disclosure allows the flow of two different gas streams simultaneously within the same processing chamber without having the two gas streams mix with each other within the processing chamber. The simultaneous flow of these first and second gases without mixing may occur without mixing even when the gas flowing at the top (or upper portion) of the processing chamber is heavier than the gas flowing at the bottom (or lower portion) of the processing chamber. The first and second gas flows at the surface of the UV window and the substrate are uniformly distributed.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

In this application, including the definitions below, the term controller may be replaced with the term circuit. The term controller may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term code, as used above, may include software, firmware, and/or microcode, and may refer to programs, routines, functions, classes, and/or objects. The term shared processor encompasses a single processor that executes some or all code from multiple controllers. The term group processor encompasses a processor that, in combination with additional processors, executes some or all code from one or more controllers. The term shared memory encompasses a single memory that stores some or all code from multiple controllers. The term group memory encompasses a memory that, in combination with additional memories, stores some or all code from one or more controllers. The term memory may be a subset of the term computer-readable medium. The term computer-readable medium does not encompass transitory electrical and electromagnetic signals propagating through a medium, and may therefore be considered tangible and non-transitory. Non-limiting examples of a non-transitory tangible computer readable medium include nonvolatile memory, volatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

What is claimed is:

1. A substrate processing system, comprising:
a processing chamber;
a first gas inlet that supplies a first gas to the processing chamber and that is arranged in a first horizontal plane;
a second gas inlet that supplies a second gas that is different than the first gas to the processing chamber and that is arranged in a second horizontal plane that is spaced from the first horizontal plane;
a first gas outlet that receives the first gas from the processing chamber and that is arranged in a third horizontal plane that is horizontally spaced from and between the first horizontal plane and the second horizontal plane; and
a second gas outlet that receives the second gas from the processing chamber and that is arranged in a fourth horizontal plane that is horizontally spaced from and between the second horizontal plane and the third horizontal plane.

2. The substrate processing system of claim 1, wherein the first gas comprises purge gas and the second gas comprises process gas.

3. The substrate processing system of claim 1, wherein the first gas is directed across a component in the processing chamber and wherein the second gas is directed across a substrate arranged on a pedestal in the processing chamber.

4. The substrate processing system of claim 3, wherein the component includes an ultraviolet window.

5. The substrate processing system of claim 1, wherein a surface of the processing chamber comprises an ultraviolet (UV) window and further comprising a UV light source configured to direct UV light through the UV window onto a substrate arranged on a pedestal in the processing chamber while the first gas and the second gas are flowing.

6. The substrate processing system of claim 5, wherein:
the first gas comprises purge gas;
the second gas comprises process gas; and
the first gas inlet directs the purge gas across a surface of the UV window while the second gas inlet directs the process gas across a surface of the substrate.

7. The substrate processing system of claim 1, wherein the first gas inlet and the second gas inlet comprise first and second manifolds, respectively, each including a plurality of holes arranged in the first and second horizontal planes, respectively.

8. The substrate processing system of claim 7, wherein the first gas outlet and the second gas outlet comprise third and fourth manifolds, respectively, each including a plurality of holes arranged in third and fourth horizontal planes, respectively.

9. The substrate processing system of claim 1, further comprising:
at least one of a first valve and a first mass flow controller arranged between a first gas source and the first gas inlet;
at least one of a second valve and a second mass flow controller arranged between a second gas source and the second gas inlet; and
a controller configured to flow the second gas across a substrate arranged on a pedestal in the processing chamber after the first gas is flowing and to not flow the second gas when the first gas is not flowing.

10. The substrate processing system of claim 1, wherein:
the first horizontal plane and the second horizontal plane are horizontally spaced by a first distance;
the first horizontal plane and the third horizontal plane are spaced between 2.5% and 25% of the first distance; and
the second horizontal plane and the fourth horizontal plane are spaced between 2.5% and 25% of the first distance.

11. A method for processing a substrate, comprising:
supplying a first gas to a processing chamber using a first gas inlet that is arranged in a first horizontal plane;
supplying a second gas that is different than the first gas to the processing chamber using a second gas inlet that is arranged in a second horizontal plane that is horizontally spaced from the first horizontal plane;
removing the first gas from the processing chamber using a first gas outlet that is arranged in a third horizontal plane that is horizontally spaced from and between the first horizontal plane and the second horizontal plane; and
removing the second gas from the processing chamber using a second gas outlet that is arranged in a fourth horizontal plane that is horizontally spaced from and between the second horizontal plane and the third horizontal plane.

12. The method of claim 11, wherein the first gas comprises purge gas and the second gas comprises process gas.

13. The method of claim 11, further comprising:
directing the first gas across a component in the processing chamber; and
directing the second gas across a substrate arranged on a pedestal in the processing chamber.

14. The method of claim 13, wherein the component includes an ultraviolet window.

15. The method of claim 11, wherein a surface of the processing chamber comprises an ultraviolet (UV) window and further comprising directing UV light from a UV light source through the UV window onto a substrate arranged on a pedestal in the processing chamber while the first gas and the second gas are flowing.

16. The method of claim 15, wherein the first gas comprises purge gas and the second gas comprises process gas, and further comprising directing the purge gas across a surface of the UV window while directing the process gas across a surface of the substrate.

17. The method of claim 11, wherein the first gas inlet and the second gas inlet comprise first and second manifolds, respectively, each including a plurality of holes arranged in the first and second horizontal planes, respectively.

18. The method of claim 17, wherein the first gas outlet and the second gas outlet comprise third and fourth manifolds, respectively, each including a plurality of holes located in the third and fourth horizontal planes, respectively.

19. The method of claim 11, further comprising flowing the second gas across a substrate arranged on a pedestal in the processing chamber after the first gas is flowing and not flowing the second gas when the first gas is not flowing.

20. The method of claim 11, wherein:
the first horizontal plane and the second horizontal plane are horizontally spaced a first distance;
the first horizontal plane and the third horizontal plane are spaced between 2.5% and 25% of the first distance; and
the second horizontal plane and the fourth horizontal plane are spaced between 2.5% and 25% of the first distance.

21. A substrate processing system, comprising:
a processing chamber including a pedestal and an ultraviolet (UV) window;
a first gas inlet that is arranged in a first horizontal plane and that supplies purge gas across a surface of the UV window in the processing chamber;
a second gas inlet that is arranged in a second horizontal plane that is spaced from the first horizontal plane and that supplies process gas that is different than the purge gas across a surface of a substrate on the pedestal in the processing chamber;
a first gas outlet that receives the purge gas from the processing chamber and that is arranged in a third horizontal plane that is horizontally spaced from and between the first horizontal plane and the second horizontal plane;
a second gas outlet that receives the process gas from the processing chamber and that is arranged in a fourth horizontal plane that is horizontally spaced from and between the second horizontal plane and the third horizontal plane; and
a UV light source configured to direct UV light through the UV window onto the substrate arranged on the pedestal while the first gas and the second gas are flowing.
